(19) United States
(12) Patent Application Publication
(10) Pub. No.: US 2024/0339385 A1
(43) Pub. Date: Oct. 10, 2024

(54) SEMICONDUCTOR PACKAGE AND METHOD OF MANUFACTURING THE SAME

(71) Applicants: NEPES LAWEH CORPORATION, Chungcheongbuk-do (KR); nepes hayyim, Laguna (PH)

(72) Inventors: Byungcheol Kim, Chungcheongbuk-do (KR); Mary Maye Melgo, Laguna (PH)

(21) Appl. No.: 18/626,080

(22) Filed: Apr. 3, 2024

(30) Foreign Application Priority Data
Apr. 4, 2023 (KR) 10-2023-0044357
Aug. 3, 2023 (KR) 10-2023-0101741

(51) Int. Cl. H01L 23/495; H01L 21/56; H01L 23/00; H01L 23/31; H01L 25/10

(52) U.S. Cl. CPC H01L 23/49575; H01L 21/568; H01L 23/3107; H01L 23/49517; H01L 23/49541; H01L 24/16; H01L 24/20; H01L 24/32; H01L 24/83; H01L 25/105; H01L 2224/16227; H01L 2224/21; H01L 2224/32245; H01L 2224/83

(57) ABSTRACT

A semiconductor package according to an embodiment includes frames; a first semiconductor device disposed on the frames; at least one conductive post disposed on the frames and laterally spaced apart from the first semiconductor device; an encapsulation member surrounding the first semiconductor device and the conductive post; and a redistribution layer disposed on the encapsulation member and electrically connected to the first semiconductor device and the conductive post.

### CROSS-REFERENCE TO RELATED APPLICATIONS

This application is based on and claims priority under 35 U.S.C. § 119 to Korean Patent Application Nos. 10-2023-0044357, filed on Apr. 4, 2023, and 10-2023-0101741, filed on Aug. 3, 2023, in the Korean Intellectual Property Office, the disclosures of which are incorporated by reference herein in their entirety.

### BACKGROUND

### 1. Field

An embodiment relates to a semiconductor package and a method of manufacturing the same.

### 2. Description of the Related Art

An electronic device is becoming smaller and lighter in accordance with a rapid development of electronics industry and needs users. Accordingly, a semiconductor package is required to have high-density input/output terminals while being small in size. Recently, research and development on a semiconductor package with a fan-out structure that forms input/output terminals outside a region where the semiconductor chip is placed and connects the input/output terminals to the semiconductor chip through redistributing has been continuously conducted.

### SUMMARY

A problem to be solved by a technical idea of a present invention is to improve reliability and productivity of a semiconductor package.

A problem to be solved by the technical idea of the present invention is not limited to the above-mentioned problem, and other problems not mentioned will be clearly understood by those skilled in the art from the following description

In order to solve the above problems, a semiconductor package comprises frames; a first semiconductor device disposed on the frames; at least one conductive post disposed on the frames and laterally spaced apart from the first semiconductor device; an encapsulation member surrounding the first semiconductor device and the conductive post; and a redistribution layer disposed on the encapsulation member and electrically connected to the first semiconductor device and the conductive post.

According to one or more embodiments, a method of manufacturing of a semiconductor package comprises providing on a carrier, at least one frame and a conductive post located on the frame; mounting on the frame, at least one semiconductor device with a connection pad; forming on the carrier, an encapsulation member surrounding side surfaces of the semiconductor device and the conductive post; removing a portion of the encapsulation member; forming on the encapsulation member, a redistribution layer electrically connected to the semiconductor device and the conductive post; and removing the carrier.

According to one or more embodiments, a method of manufacturing of a semiconductor package comprises mounting on a first carrier, a semiconductor device with a connection pad and a dummy board with a conductive post; forming on the first carrier, an encapsulation member surrounding the connection pad, the semiconductor device, and the conductive post; removing a portion of the encapsulation member, a portion of the conductive post, and a portion of the connection pad; forming a redistribution layer electrically connected to the encapsulation member, the conductive post, and the connection pad; removing the first carrier and placing a process object on a second carrier to be adjacent to the redistribution layer; removing a portion of the semiconductor device, a portion of the encapsulation member, the conductive post, and all of the dummy board; forming at least one frame on a plane where a back surface where a part of the semiconductor device is removed and one surface of the encapsulation member forms a coplanar; and removing the second carrier.

In a semiconductor package and a method of manufacturing a semiconductor package according to an embodiment of the present invention, reliability and productivity of the semiconductor package may be improved through simplification of a semiconductor package structure. Additionally, a size of the semiconductor package can be reduced and the performance of the semiconductor package can be improved.

### BRIEF DESCRIPTION OF THE DRAWINGS

FIG. 1 is a cross-sectional view showing a semiconductor package according to an exemplary embodiment of a present invention.

FIG. 2A is a cross-sectional view illustrating a semiconductor package according to an exemplary embodiment of a present invention.

FIG. 2B is a cross-sectional view illustrating a semiconductor package according to an exemplary embodiment of a present invention.

FIG. 3 is a cross-sectional view illustrating a semiconductor package according to an exemplary embodiment of a present invention.

FIGS. 4A to 4E are cross-sectional views for explaining a method of manufacturing a semiconductor package according to an exemplary embodiment of a present invention.

FIGS. 5A to 5E are cross-sectional views for explaining a method of manufacturing a semiconductor package according to an exemplary embodiment of the present invention.

### DETAILED DESCRIPTION

Hereinafter, embodiments of the technical idea of the present disclosure will be described in detail with reference to accompanying drawings. The same reference numerals are used for the same components in the drawings, and duplicate descriptions thereof are omitted.

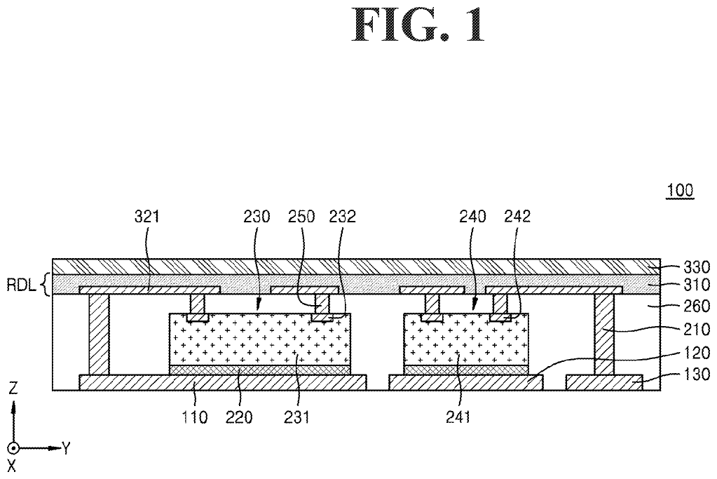

FIG. 1 is a cross-sectional view showing a semiconductor package 100 according to an exemplary embodiment of the present invention.

Referring to FIG. 1, the semiconductor package 100 can include a first semiconductor device 230, a second semiconductor device 240, a connection terminal 250 disposed on the first semiconductor device 230 and the second semiconductor device 240, an encapsulation member 260 surrounding the first semiconductor device 230 and the second semiconductor device 240, a redistribution layer (RDL) disposed on the encapsulation member 260, a dielectric layer 330 provided on the redistribution layer, a first frame 110 having an upper surface on which a first semiconductor device 230 is disposed, a second frame 120 having an upper surface on which a second semiconductor device 240 is disposed, and a third frame 130 electrically connected to the redistribution layer (RDL) and located laterally spaced apart from the second frame 120.

The semiconductor package 100 may be a fan-out semiconductor package. In this specification, a horizontal refers to a X-Y plane, a first horizontal direction refers to a X direction, and a second horizontal direction refers to a Y direction. A vertical refers to a direction perpendicular to the X-Y plane, and a vertical direction refers to a Z direction.

The first semiconductor device 230 may include a first semiconductor substrate 231 and a first chip pad 232. For example, the first semiconductor substrate 231 may include silicon (Si) and may be formed from a semiconductor wafer. The first semiconductor substrate 231 may include an active surface and an inactive surface located on opposite sides of each other. A semiconductor device layer may be formed on the active surface of the first semiconductor substrate 231. A plurality of various types of individual devices can be formed in the semiconductor device layer. The first chip pad 232 may be provided on an upper surface of the first semiconductor device 230. The first chip pad 232 may be electrically connected to an individual device formed in the semiconductor device layer. For example, the plurality of individual devices may be microelectronic devices, for example, MOSFET (Metal-Oxide-Semiconductor Field Effect Transistor) such as CMOS transistor (Complementary Metal-Oxide-Semiconductor transistor), etc., system LSI (Large Scale Integration), image sensors such as CIS (CMOS Imaging Sensor), etc., MEMS (Micro-Electro-Mechanical System), active devices, and passive devices, etc. The first semiconductor device 230 may further include a passivation layer (not shown) that protects the active surface. The passivation layer is provided on one surface of the first semiconductor substrate 231 and may include an opening to expose a portion of the first chip pad 232. In example embodiments, the first semiconductor device 230 may be a memory chip. In example embodiments, the first semiconductor device 230 may be a logic chip.

The second semiconductor device 240 may be disposed to be spaced apart from a side surface of the first semiconductor device 230. The second semiconductor device 240 may include a second semiconductor substrate 241 and a second chip pad 242. For example, the second semiconductor substrate 241 may include silicon (Si) and may be formed from a semiconductor wafer. The second semiconductor substrate 241 may include an active surface and an inactive surface located on opposite sides of each other. A semiconductor device layer may be formed on the active surface of the second semiconductor substrate 241. The first chip pad 232 and the second chip pad 242 may be made of a metal containing at least one of copper (Cu), aluminum AL, and gold (Au).

In an exemplary embodiment of the present invention, the semiconductor package 100 may include at least one semiconductor device. In FIG. 1, a first semiconductor device 230 and a second semiconductor device 240 are shown. However, for example, one semiconductor device or three or more semiconductor devices may be included in the semiconductor package 100. The number of semiconductor devices included in the semiconductor package 100, which is an exemplary embodiment of the present invention, can be selected and appropriately disposed as needed, and the present invention is not limited to the number of semiconductor devices.

In an exemplary embodiment, in addition to the first semiconductor device 230 and the second semiconductor device 240 disposed to be spaced apart in the second direction (Y direction) as shown in FIG. 1, another semiconductor device disposed to be spaced apart from the first semiconductor device 230 and the second semiconductor device 240 in the first direction (X direction) may be provided in the semiconductor package 100 of an exemplary embodiment of the present invention.

A connection terminal 250 may be provided on the first chip pad 232 of the first semiconductor device 230 and the second chip pad 242 of the second semiconductor device 240. The connection terminal 250 may electrically connect a redistribution line pattern 321 of the redistribution layer (RDL), which will be described later, with the first semiconductor device 230 and the second semiconductor device 240. For example, the connection terminal 250 may be a stud bump. The connection terminal 250 may be made of a metal containing at least one of copper (Cu), silver (Ag), gold (Au), lead (Pd), and tin (Sn).

The first semiconductor device 230 may be disposed by attaching a back surface to a chip attachment layer 220 on the first frame 110. A shape in which the first semiconductor device 230 overlaps on the first frame 110 may be included in a shape of the X-Y plane of the first frame 110. Heat generated when the first semiconductor device 230 operates may be conducted to the first frame 110 and transmitted to an outside through the first frame 110. Accordingly, the heat generated by the first semiconductor device 230 can be easily dissipated through the first frame 110 disposed adjacent to the first semiconductor device 230.

The first frame 110, the second frame 120, and the third frame 130 may be made of a metal containing at least one of copper (Cu), silver (Ag), gold (Au), lead (Pd), and tin (Sn). The frames including the first frame 110, the second frame 120, and the third frame 130 may be disposed adjacent to a lower surface of the semiconductor device while being electrically connected to the semiconductor device, if necessary, or, may be electrically connected to the semiconductor device but may be placed spaced apart from the semiconductor device, or may be placed adjacent to a lower surface of the semiconductor device without being electrically connected to the semiconductor device.

In an exemplary embodiment, the first frame 110 may be disposed adjacent to a back surface of the first semiconductor device 230 and electrically connected to the semiconductor devices through a conductive post 210. The second frame 120 is disposed adjacent to a back surface of the second semiconductor device 240, but may not be electrically connected to the semiconductor devices. The third frame 130 is not disposed adjacent to the back surfaces of the first semiconductor device 230 and the second semiconductor device 240, but may be electrically connected to the semiconductor devices through the conductive post 210. The arrangement and connection of the frames may be selected as needed.

A conductive post 210 may be disposed laterally spaced from the first semiconductor device 230 and electrically connected to a redistribution layer (RDL), which will be described later, on the first frame 110. Additionally, a conductive post 210 may be disposed laterally spaced from the second semiconductor device 240 and electrically connected to a redistribution layer (RDL), which will be described later, on the third frame 130. The conductive post 210 may be made of a metal containing at least one of copper (Cu), silver (Ag), gold (Au), lead (Pd), and tin (Sn).

An encapsulation member 260 may surround a portion of a front surface and side surfaces adjacent to the active surfaces of the first semiconductor device 230 and the second semiconductor device 240, and may surround side surfaces of the conductive post 210. The encapsulation member 260 forms coplanar with the lower surfaces of the frames and may surround at least a portion of the side and upper surfaces of the frames.

The encapsulation member 260 may be formed from a thermosetting resin such as an epoxy resin, a thermoplastic resin such as polyimide, or a resin containing a reinforcing material such as an inorganic filler, specifically, ABF (Ajinomoto Build-up Film), FR-4, BT, etc. Alternatively, the encapsulation member 260 may be formed from a molding material such as EMC or a photosensitive material such as a photo imagable encapsulant (PIE). In some embodiments, a portion of the encapsulation member 260 may be made of an insulating material such as a silicon oxide film, a silicon nitride film, or a silicon oxynitride film.

A redistribution layer (RDL) may be provided on one surface of the encapsulation member 260. The redistribution layer (RDL) may include a redistribution insulating layer 310 and a redistribution line pattern 321. A portion of the redistribution line pattern 321 may be in contact with a connection terminal 250 that is electrically connected to the first semiconductor device 230 or the second semiconductor device 240. Additionally, a portion of the redistribution line pattern 321 may be connected to one end surface of the conductive post 210 and electrically connected to the frames.

The redistribution insulating layer 310 may be made of a material containing photosensitive polyimide (PSPI), photosensitive insulating material (Photo Imagable Dielectric), etc. The redistribution layer (RDL) can be formed by a redistribution process. The redistribution layer (RDL) may include a plurality of redistribution insulating layers 310 and a plurality of redistribution line patterns 321. Unlike this, the redistribution layer (RDL) may be composed of a plurality of stacked redistribution insulating layers 310. Additionally, a plurality of redistribution line patterns 321 may be provided between the plurality of redistribution insulating layers 310 stacked. A plurality of redistribution line patterns 321 of different layers may be electrically connected to each other by a redistribution via pattern (not shown).

A dielectric layer 330 may be provided on the redistribution layer (RDL). The dielectric layer 330 may be composed of an insulating material. The dielectric layer 330 may be referred to as a lamination film.

In the semiconductor package 100, which is an exemplary embodiment of the present invention, the semiconductor device can facilitate heat dissipation through a frame in which the semiconductor device is disposed adjacent to an upper portion, so the thermal characteristics of the semiconductor package 100 can be improved. In addition, like the first frame 110 described above, for example, since the first semiconductor device 230 may be electrically connected to the first frame 110 through the redistribution layer (RDL) and the conductive post 210, so that heat dissipation can be performed simultaneously with electrical connection to an outside.

In the semiconductor package 100, which is an example embodiment of the present invention, the semiconductor devices are not connected by wires to the frames disposed at the back surface of the semiconductor devices, and the frame and semiconductor devices are electrically connected through a redistribution layer (RDL) and conductive post 210. Therefore, a process of connecting a separate wire is unnecessary, since the electrical connection is made by the redistribution layer (RDL) after forming the encapsulation member, a structure of the semiconductor package 100 is simpler than that of electrical connection through wires, so that the reliability of the semiconductor package 100 can be improved. Additionally, a size of the semiconductor package can be reduced compared to when electrically connected through wires, or more semiconductor chips can be included in the semiconductor package. Accordingly, the size of the semiconductor package can be reduced or the performance of the semiconductor package can be improved.

In addition, the semiconductor package 100 electrically connects semiconductor devices and frames through a redistribution layer (RDL) and conductive post 210, rather than a wire. For this reason, more semiconductor packages can be mass-produced simultaneously compared to when using wires, and the productivity of the semiconductor package 100 can be improved.

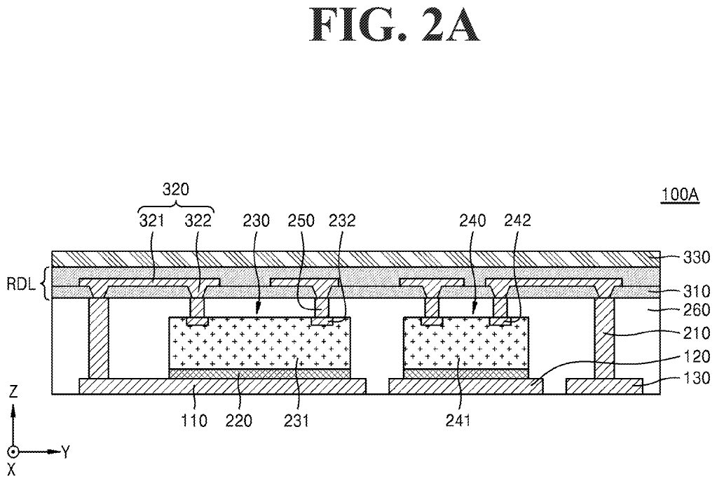

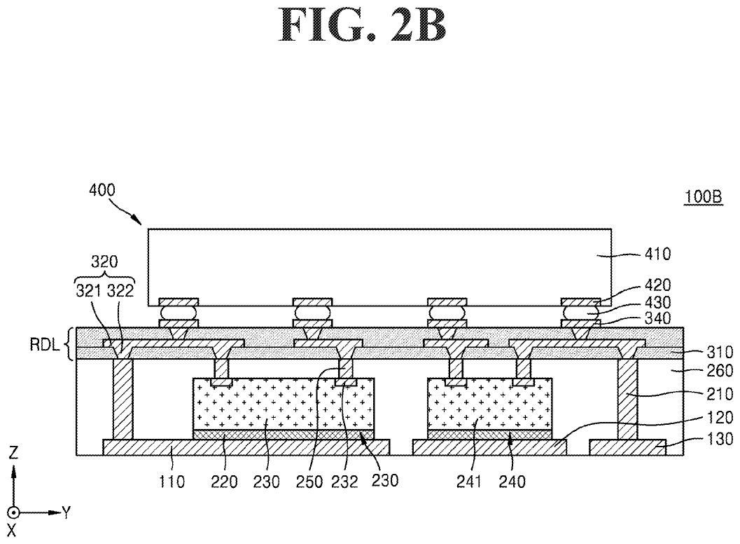

FIG. 2A is a cross-sectional view illustrating a semiconductor package 100A according to an exemplary embodiment of the present invention. FIG. 2B is a cross-sectional view illustrating a semiconductor package 100B according to an exemplary embodiment of the present invention.

Referring to FIG. 2A, a semiconductor package 100A, which is an exemplary embodiment of the present invention, includes a redistribution layer (RDL) and may further include a redistribution via pattern 322. The redistribution via pattern 322 may be electrically connected by contacting the connection terminal 250 via a portion of the redistribution insulating layer 310. The redistribution via pattern 322 may connect a plurality of redistribution line patterns 321 provided between a plurality of redistribution insulating layers 310.

Referring to FIG. a semiconductor package 100B, which is an exemplary embodiment of the present invention, may have an upper semiconductor device 400 mounted on a redistribution layer (RDL). The upper semiconductor device 400 may be electrically connected to the first semiconductor device 230 and the second semiconductor device 240 through a redistribution layer (RDL). The upper semiconductor device 400 may be electrically connected to the frames through a redistribution layer (RDL) and a conductive post 210. The upper semiconductor device 400 is a semiconductor package and may include a semiconductor chip.

The upper semiconductor device 400 may be electrically connected to an upper chip pad 340 provided on the redistribution layer (RDL) through the upper chip pad 320 and the redistribution layer (RDL) through the upper connection terminal 430.

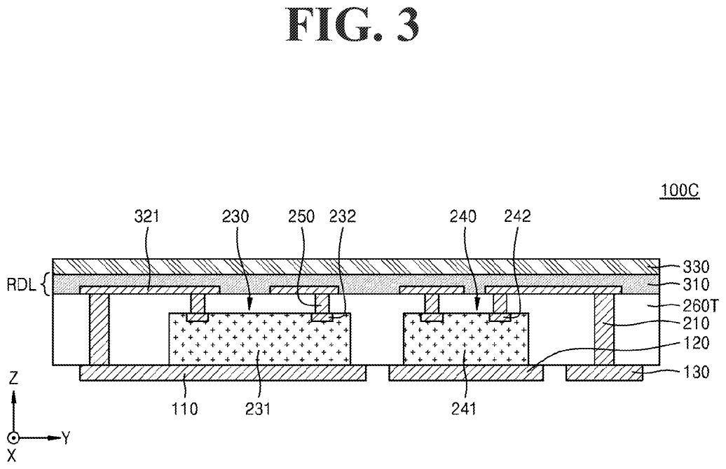

FIG. 3 is a cross-sectional view illustrating a semiconductor package 100C, which is an exemplary embodiment of the present invention. A description within a range duplicating the above description may be omitted.

Referring to FIG. 3, an encapsulation member 260T provided in a semiconductor package 100C, which is an exemplary embodiment of the present invention, may not surround side surfaces of the frames. That is, the side surfaces of the first frame 110, the second frame 120, and the third frame 130 are not wrapped, and at the same time, a lower surface of the encapsulation member 260T and a lower surface of the frames may not be coplanar with each other. However, surfaces facing the first semiconductor device 230 and the second semiconductor device 240 of the frames including the first frame 110, the second frame 120, and the third frame 130, and the lower surface of the encapsulation member 260T may be coplanar with each other.

A chip attachment layer 220 may not be provided between the first semiconductor device 230 and the second semiconductor device 240 and the frames. Unlike in FIGS. 1 to 2B, a chip attachment layer 220 may not be provided between the first frame 110 and the first semiconductor device 230 and between the second frame 120 and the second semiconductor device 240. That is, the first frame 110 and the first semiconductor device 230 may be in direct contact, and the second frame 120 and the second semiconductor device 240 may be in direct contact. This is due to the manufacturing method of the semiconductor package 100C of an exemplary embodiment of the present invention, which will be described later.

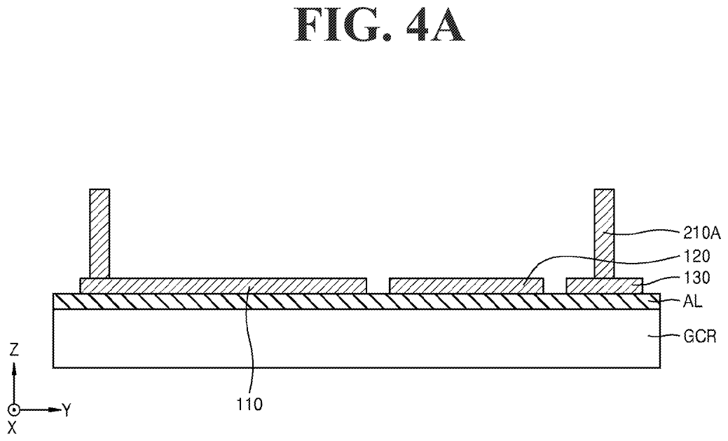

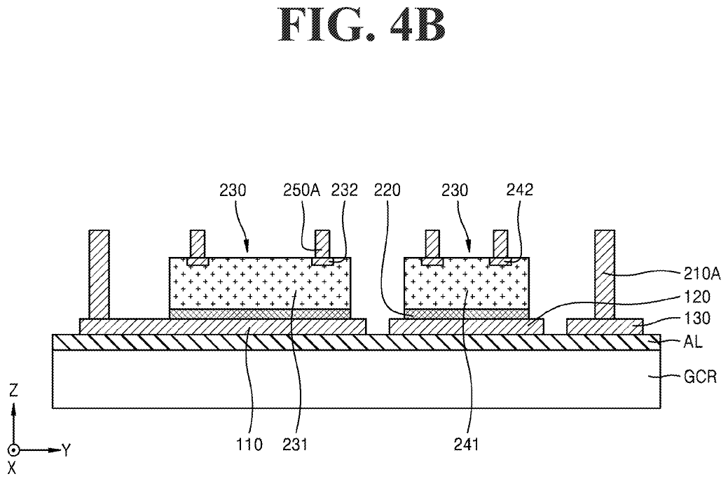

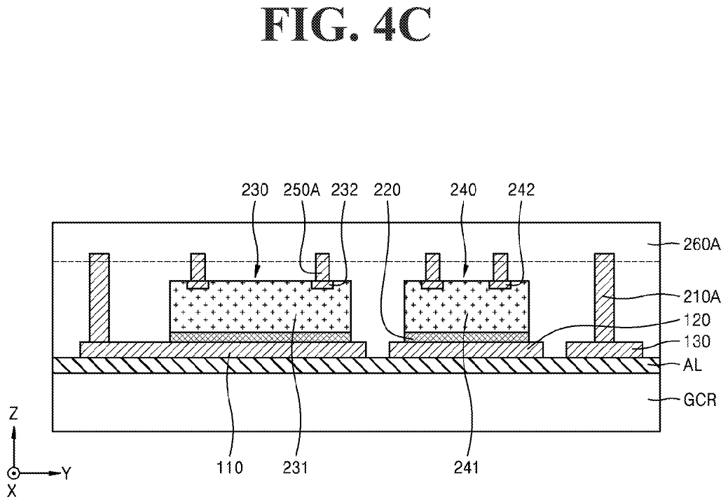

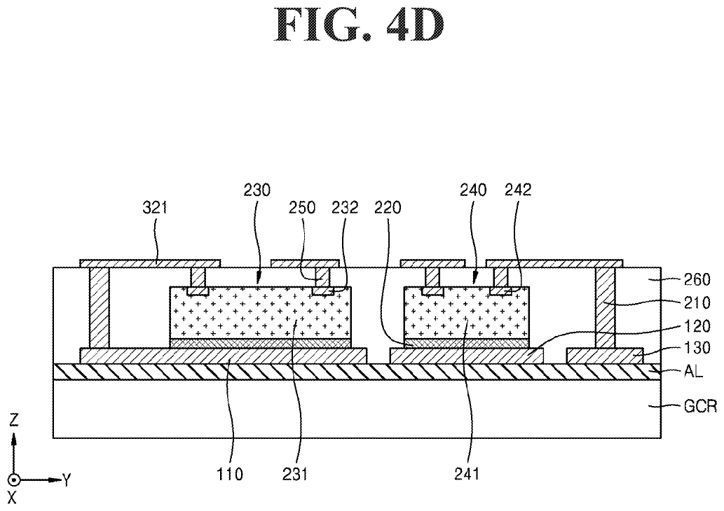

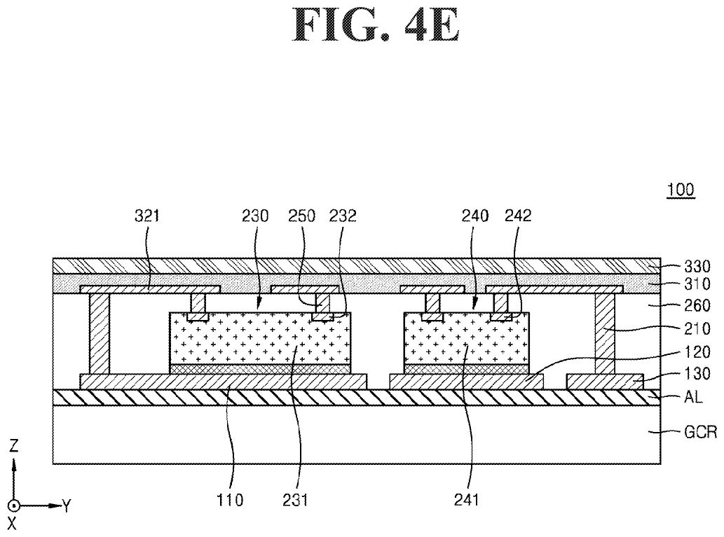

Referring to FIG. 4A, an adhesive layer AL may be provided on the carrier. In addition, a first frame 110, a second frame 120, and a third frame 130 may be disposed on the adhesive layer AL. A conductive post 210A may be formed on the first frame 110 and the third frame 130.

The carrier may be, for example, a glass carrier (GCR). A conductive post 210A may be disposed on a glass carrier GCR in which frames including the first frame 110, the second frame 120, and the third frame 130 are pre-disposed. That is, the frames may be pre-disposed on the glass carrier (GCR) as a pre-plated lead frame (PPF) before a process proceeds. In this specification, the frame may be referred to as a lead frame.

The adhesive layer AL may be an epoxy-based heat release material that loses adhesive force when heated. In other embodiments, the adhesive layer AL may be an ultraviolet (UV) adhesive that loses adhesive properties when exposed to UV light. The adhesive layer AL may be dispensed and cured as a liquid, or may be a laminate film disposed on the glass carrier GCR. The adhesive layer AL may have a high flatness.

Referring to FIG. 4B, a first semiconductor device 230 and a second semiconductor device 240 may be disposed on the first frame 110 and the second frame 120 through the chip attachment layer 220, respectively. The connection terminals 250A on the first semiconductor device 230 and the second semiconductor device 240 may be pre-formed on the first semiconductor device 230 and the second semiconductor device 240.

Referring to FIG. 4C, an encapsulation member 260A may be formed on the adhesive layer AL. The encapsulation member 260A may surround the side surfaces of the first frame 110, the second frame 120, and the third frame 130. The encapsulation member 260A may cover at least a portion of the side and upper surfaces of the first semiconductor device 230 and the second semiconductor device 240, and the side surface of the conductive post 210A. In a next process, a portion of the encapsulation member 260A, a portion of the connection terminal 250A, and a portion part of the conductive post 210A may be removed. For example, a process of removing may be performed through a CMP (Chemical-Mechanical Polishing) process.

Referring to FIG. 4D, a portion of the encapsulation member 260A, a portion of the connection terminal 250A, and a portion of the conductive post 210A may be removed along a dotted line shown in FIG. 4C. Accordingly, a removed cross section of the encapsulation member 260, a removed cross section of the connection terminal 250, and a removed cross section of the conductive post 210 may be coplanar. In other words, a vertical level of a removed cross section of the encapsulation member 260, a removed cross section of the connection terminal 250, and a removed cross section of the conductive post 210 may be substantially the same based on the glass carrier (GCR). Thereafter, a redistribution line pattern 321 electrically connected to the connection terminal 250 and the conductive post 210 may be formed on the upper surface of the encapsulation member 260.

Referring to FIG. 4E, a redistribution layer (RDL) including a redistribution line pattern 321 and a redistribution insulating layer 310 may be formed. A plurality redistribution via patterns (not shown) may be provided to connect a plurality of redistribution insulating layers 310 and a plurality of redistribution line patterns 321 while passing through the redistribution insulating layer 310. A dielectric layer 330 is formed on the redistribution layer (RDL), and the glass carrier (GCR) attached to the lower surfaces of the frames may be removed by irradiating ultraviolet rays (UV) or heating the adhesive layer (AL).

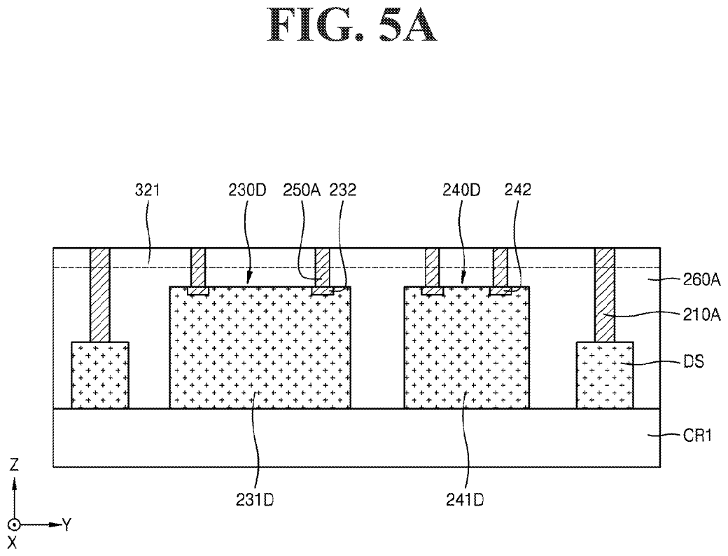

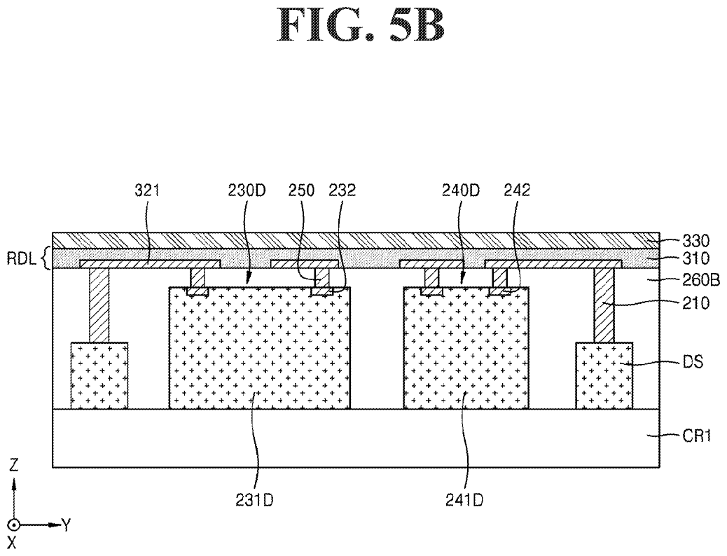

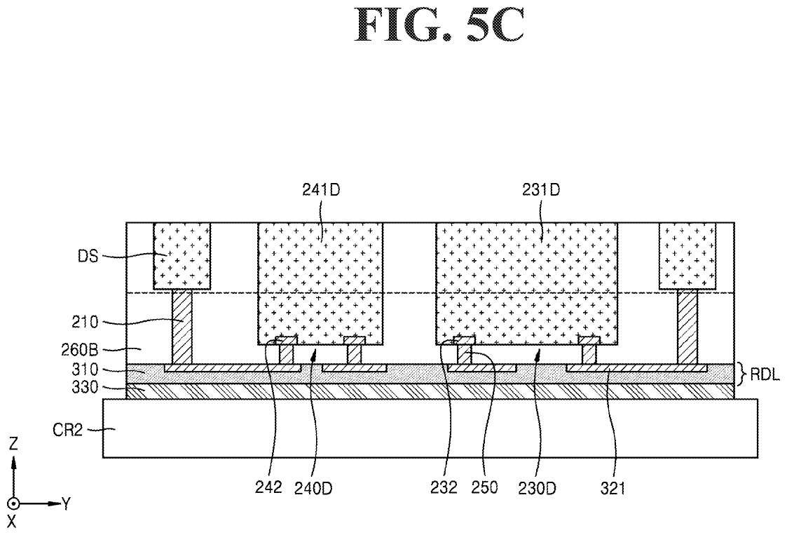

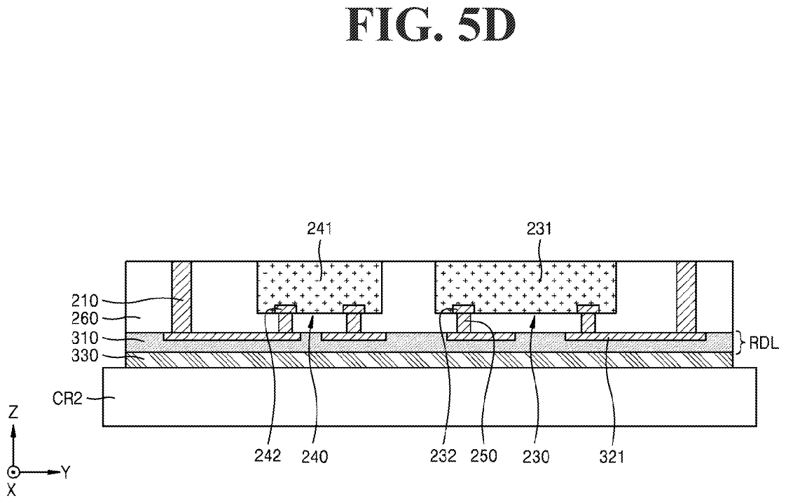

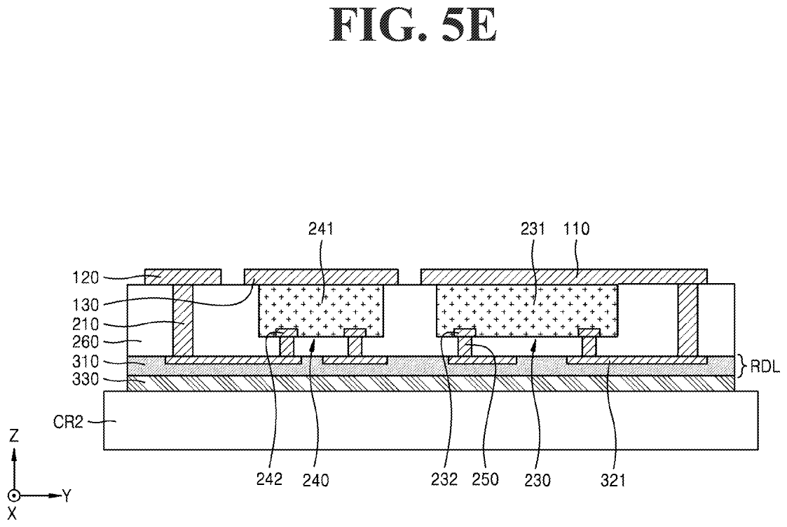

FIGS. 5A to 5E are cross-sectional views for explaining a method of manufacturing a semiconductor package 100C, which is an exemplary embodiment of the present invention.

Referring to FIG. 5A, a first semiconductor device 230D and a second semiconductor device 240D, each provided with a connection terminal 250A, may be placed on the first carrier CR1. In addition, a conductive post 210A is provided on the dummy board DS, and accordingly, the dummy board DS may be placed on the first carrier CR1. The dummy board DS is removed in a process to be described later, and therefore, the dummy board DS may not include a semiconductor element device layer, unlike the first semiconductor device 230D and the second semiconductor device 240D.

The encapsulation member 260A may be formed to surround the sides surface of the first semiconductor device 230D, the second semiconductor device 240D, the conductive post 210A, the dummy board DS, and the connection terminal 250A on a first carrier CR1. A dotted line in FIG. 5A indicates a region where a portion of the encapsulation member 260A, a portion of the conductive post 210A, and a portion of the connection terminal 250A will be removed in a process to be described later.

Referring to FIG. 5B, after an upper region indicated by a dotted line in FIG. 5A is removed through, for example, CMP, a redistribution layer (RDL) including a redistribution line pattern 321 and a redistribution insulating layer 310 may be formed. A dielectric layer 330 may be formed on the redistribution layer (RDL). The dielectric layer 330 may be a lamination layer.

Referring to FIG. 5C, the first carrier CR1 may be removed from a process result object of FIG. 5B, and the process result object may be placed on the second carrier CR2 so that the dielectric layer 330 is in contact with the process result object. The dotted line in FIG. 5C indicates a portion to be removed in a subsequent process. The dummy board DS is for forming the conductive post 210D and is completely removed. A portion of the first semiconductor device 230D and the second semiconductor device 240D in a direction opposite to the active surface may be removed. Thereafter, a state of the process result object can be observed by Automated Optical Inspection (AOI).

Referring to FIG. 5D, a portion of the encapsulation member 260B, a portion of the first semiconductor device 230D, a portion of the second semiconductor device 240D, a portion of the conductive post 210D, and the dummy board DS can be removed along the dotted line in FIG. 5C. Based on the removed surface, a back surface of the first semiconductor device 230 (i.e., the inactive surface opposite to the active surface), a back surface of the second semiconductor device 240, one end surface of the conductive post 210, and end surface of the encapsulation member 260 may be coplanar.

Referring to FIG. 5E, the first frame 110, the second frame 120, and the third frame 130 may be formed on the upper surface of the encapsulation member 260. In an exemplary embodiment, the first frame 110 is spaced apart from the first semiconductor device 230 at the back surface of the first semiconductor device 230 and the side surface of the first semiconductor device 230, but may be disposed on one end surface of an adjacent conductive post 210. The second frame 120 may be disposed at the back surface of the second semiconductor device 240. The third frame 130 is spaced apart from the second semiconductor device 240 at the side surface of the second semiconductor device 240, but can be disposed on one end surface of an adjacent conductive post 210. The arrangement of the frames may vary depending on need, but is not limited thereto. Thereafter, when the second carrier CR2 is removed, the semiconductor package 100C, which is an exemplary embodiment of the present invention, can be formed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

1. A semiconductor package comprising:
frames;
a first semiconductor device disposed on the frames;
at least one conductive post disposed on the frames and laterally spaced apart from the first semiconductor device;
an encapsulation member surrounding the first semiconductor device and the conductive post; and
a redistribution layer disposed on the encapsulation member and electrically connected to the first semiconductor device and the conductive post.

2. The semiconductor package of claim 1, wherein the frames include:
a first frame disposed at a back surface of the first semiconductor device and electrically connected to the conductive post,
a second frame disposed at the back surface of the first semiconductor device and spaced apart from the conductive post, and
a third frame disposed at the back surface of the first semiconductor device and electrically connected to the conductive post,
wherein the first frame to the third frame are selectively provided.

3. The semiconductor package of claim 2, wherein the encapsulation member surrounds side surfaces of the frames, and
wherein one surface of the encapsulation member is coplanar with a surface opposite to a surface of the frames close to the first semiconductor device.

4. The semiconductor package of claim 3, further comprising:
an adhesive layer disposed between the first semiconductor device and the frames.

5. The semiconductor package of claim 4, wherein the redistribution layer includes a redistribution pattern and a redistribution insulating layer, and
wherein the redistribution layer includes a single layer of the redistribution insulating layer.

6. The semiconductor package of claim 2, wherein one surface of the encapsulation member is coplanar with the surface of the frames close to the first semiconductor device and contacts at least a portion of a surface of the frame close to the first semiconductor device, and
wherein the encapsulation member is spaced apart from side surfaces of the frames.

7. The semiconductor package of claim 2, further comprising:
an upper semiconductor device, and
wherein the upper semiconductor device is mounted on the redistribution layer.

8. A method of manufacturing of a semiconductor package comprising:
providing on a carrier, at least one frame and a conductive post located on the frame;
mounting on the frame, at least one semiconductor device with a connection pad;
forming on the carrier, an encapsulation member surrounding side surfaces of the semiconductor device and the conductive post;
removing a portion of the encapsulation member;
forming on the encapsulation member, a redistribution layer electrically connected to the semiconductor device and the conductive post; and
removing the carrier.

9. The method of claim 8, further comprising:
forming a redistribution layer; and
mounting an upper semiconductor device on the redistribution layer.

10. The method of claim 8, wherein the carrier is a glass carrier, and
wherein the frame and the conductive post are pre-disposed on the glass carrier.

11. A method of manufacturing of a semiconductor package comprising:
mounting on a first carrier, a semiconductor device with a connection pad and a dummy board with a conductive post;
forming on the first carrier, an encapsulation member surrounding the connection pad, the semiconductor device, and the conductive post;
removing a portion of the encapsulation member, a portion of the conductive post, and a portion of the connection pad;
forming a redistribution layer electrically connected to the encapsulation member, the conductive post, and the connection pad;
removing the first carrier and placing a process object on a second carrier to be adjacent to the redistribution layer;
removing a portion of the semiconductor device, a portion of the encapsulation member, the conductive post, and all of the dummy board;
forming at least one frame on a plane where a back surface where a part of the semiconductor device is removed and one surface of the encapsulation member forms a coplanar; and
removing the second carrier.

12. The method of claim 11, wherein the frame is disposed to contact the back surface of the semiconductor device or one end surface of the conductive post, or is disposed to contact the back surface of the semiconductor device and one end surface of the conductive post.
